(19) United States
(12) Patent Application Publication
(10) Pub. No.: US 2017/0309427 A1
(43) Pub. Date: Oct. 26, 2017

(54) ARRANGEMENT AND METHOD FOR SWITCHING OPEN CONTACT GAPS USING SWITCHING DEVICES

(71) Applicant: SIEMENS AKTIENGESELLSCHAFT, Munchen (DE)

(72) Inventors: Benjamin Sewiolo, Obermichelbach (DE); Andreas Ziroff, München (DE)

(21) Appl. No.: 15/513,506

(22) PCT Filed: Aug. 26, 2015
(86) PCT No.: PCT/EP2015/069492

§ 371 Date: Mar. 22, 2017

(30) Foreign Application Priority Data
Sep. 22, 2014 (DE) 10 2014 219 089.4

(51) Int. Cl. H01H 33/42; H01H 33/02; G01R 15/14; H01B 17/00; H02H 1/00; H01H 33/666

(52) U.S. Cl. CPC H01H 33/423; H02H 1/0061; H01H 33/6662; G01R 15/14; H01B 17/005; H01H 33/027

(57) ABSTRACT

The invention relates to an arrangement and a method for switching clearances between contacts by means of switching devices, wherein an energy provides an actuator energy for at least one switching device, in particular a vacuum interrupter.

This application is the National Stage of International Application No. PCT/EP2015/069492, filed Aug. 26, 2015, which claims the benefit of German Patent Application No. 10 2014 219 089.4, filed Sep. 22, 2014. The entire contents of these documents are hereby incorporated herein by reference.

### BACKGROUND

The present embodiments relate to switching using switching devices.

The use of switches in electrical engineering is known. Switches in electronics are operated in a current and voltage range that generally does not impose any particular load or requirements on the switch.

In contrast, switches in medium-voltage technology are used with different tasks (e.g., as circuit breakers, load switches, isolating switches, load-break switches, grounding switches or protective switches). On account of a generally more complex structure, the switches are also referred to as switching devices in a generalized manner.

In this case, given loads are no-load switching, switching of operating currents, and switching of short-circuit currents.

For example, the switching device is intended to provide as little resistance as possible to the flow of operating and short-circuit currents in the closed state. In contrast, the open contact gap is to safely withstand the voltages occurring at the open contact gap in the open state.

All live parts are to be sufficiently insulated with respect to ground and from phase to phase when the switching device is open or closed.

The switching device is intended to be able to close the circuit when a voltage is applied. In the case of isolators, this condition is only for the de-energized state, apart from small charging currents. In addition, the switching device is intended to be able to open the circuit when current flows (this requirement is not made for isolators).

The switching device is also intended to cause switching overvoltages that are as low as possible.

Known switching devices that meet these requirements use vacuum interrupters, as shown in FIG. 1. The switching devices are fastened to a frame with the aid of insulators (e.g., in the case of a circuit breaker, as shown in FIGS. 2 and 3) and are mechanically switched with the aid of a lever.

On account of the high mechanical load, this mechanical switching operation allows 10,000-120,000 switching cycles depending on the model according to the data sheet, the drives being oiled after 10,000 switching cycles, and the vacuum interrupters having to be replaced after 30,000 switching cycles.

In this case, the entire drive mechanism with trip elements, auxiliary switches, display, and actuation devices is accommodated in a drive box.

The closing spring is tensioned electrically or manually. The closing spring latches after the tensioning operation has ended and is used as a mechanical energy store. The force from the drive to the switch poles is transmitted via switch rods.

For switching-on, the closing spring is unlatched mechanically or is unlatched electrically by remote actuation. During the switching-on operation, the closing spring tensions the opening or contact pressure springs. The closing spring that is now unloaded is automatically tensioned again by the drive motor or manually. Manual unloading has the disadvantage of the presence of a person who is also exposed to hazards under certain circumstances.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a method and an arrangement for switching open contact gaps using switching devices are provided.

In the arrangement according to one or more of the present embodiments for switching open contact gaps using switching devices, energy transmission of radio-frequency energy provides actuator energy for at least one switching device (e.g., a vacuum interrupter).

The practice of transmitting and providing the radio-frequency energy dispenses with manual intervention for switching. This enables and supports the fact that the use of mechanical components and also mechanical operations is minimized, with the result that wear is considerably reduced. In addition, radio-frequency energy transmission is associated with the possibility of transmitting information on the same path in a bidirectional manner.

This also applies, for example, to the use of a guide for the waves during radio-frequency energy transmission according to a development in which the switching device is mechanically connected to the radio-frequency source in a non-conductive manner (e.g., via a dielectric waveguide). The switching device includes a converter that converts the transmitted energy into actuator energy. In addition to the transmission of the energy (e.g., transmission of the power) used for switching, further advantages of this development lie in the insulation and stabilization of the arrangement if a dielectric waveguide is involved. Heat that arises may be dissipated via the waveguide.

An alternative to this is the development of the arrangement, according to which, for the purpose of transmitting energy, the radio-frequency energy is emitted as an electromagnetic wave to the switching device without a medium guiding the waves (e.g., a waveguide). The switching device includes a converter that converts the transmitted energy into actuator energy.

If the arrangement is developed such that the converters are in the form of at least one rectifier arrangement, the radio-frequency energy is transformed into electrical variables that are suitable for energy storage or for electrically operated switches, as are provided in the development in which electrically operated switches (e.g., relay switches) are connected downstream of the energy transmission as actuators.

If the converters are formed from at least two parallel rectifier arrangements, higher radio-frequency (RF) powers may be transmitted.

In one development, the waveguide includes solid dielectric material (e.g., aluminum oxide, Teflon, HDPE or hot-pressed silicon carbide). Adaptation to the given requirements and optimizations is possible depending on the choice of material. With higher thermal conductivity, silicon carbide, for example, contributes to better heat dissipation of the arrangement.

Alternatively or additionally, the arrangement may be developed such that the waveguide is formed from a flexible material filled with dielectric liquids. This makes it possible to form geometric structures (e.g., that may contribute to mechanically and electrically optimizing the arrangement).

If at least parts of the elements of the switching arrangement are provided with sensors, operating information relating to parts of the interrupter (e.g., the mechanical actuator) may also be transmitted via the waveguide in the opposite direction to the energy transmission or in a bidirectional manner. This may contribute to the ease of servicing of the interrupter and may indicate a possible fault in good time and may possibly prevent failure.

In the method according to one or more of the present embodiments for switching open contact gaps using switching devices, energy transmission of radio-frequency energy provides actuator energy for at least one switching device (e.g., a vacuum interrupter). Through respective features, the method lays the foundation for using the advantages provided by the arrangement according to one or more of the present embodiments and corresponding developments.

### BRIEF DESCRIPTION OF THE DRAWINGS

FIG. 1 shows a switching device formed by vacuum interrupters;

FIG. 2 shows a typical use of a vacuum tube switching device as a circuit breaker;

FIG. 3 shows a switching device of the circuit breaker in a side view; and

FIG. 4 shows an exemplary embodiment in a side view.

### DETAILED DESCRIPTION

FIG. 1 illustrates a switching device formed by a vacuum interrupter. Typical structure includes a drive and a connecting bolt, a guide for the connecting bolt, and a movable contact piece that is mounted, in a manner surrounded by folding bellows, in a switching chamber. The switching chamber is encased by an insulator. A stationary contact piece is also mounted in the switching chamber, opposite the movable contact piece, and is terminated in a connection disk.

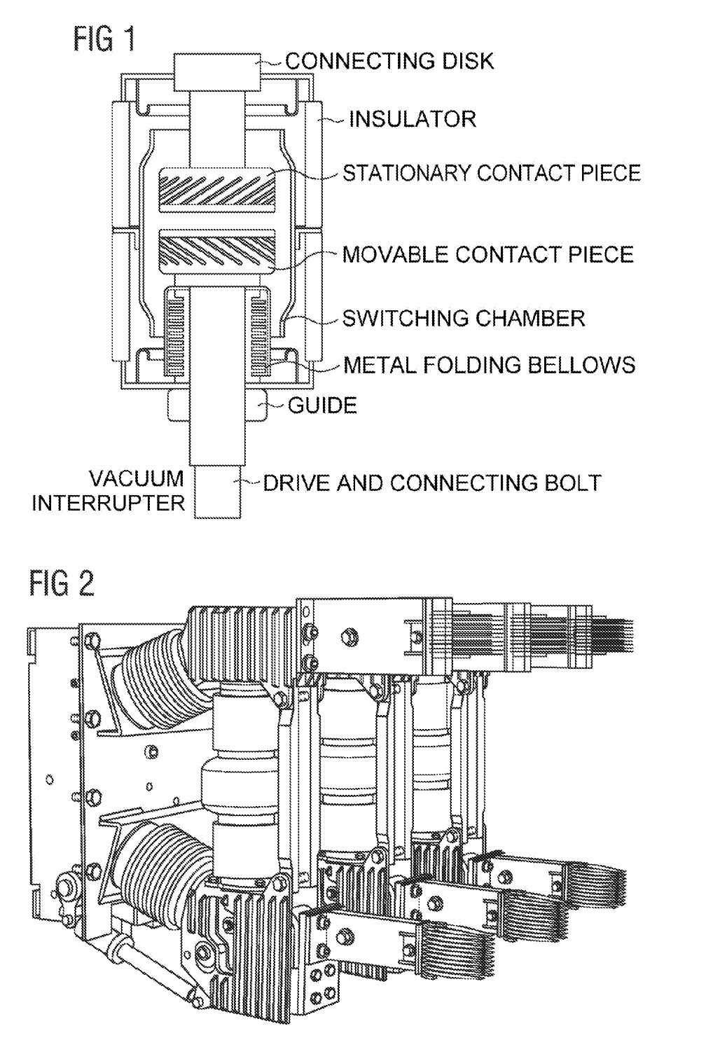

FIG. 2 illustrates a plurality of the switching devices illustrated in the previous figure in a manner installed in a circuit breaker arrangement. The left-hand part of FIG. 2 illustrates a lever that moves the drive and connecting bolt during a switching operation and brings together or separates the two contact pieces and therefore closes or opens the circuit.

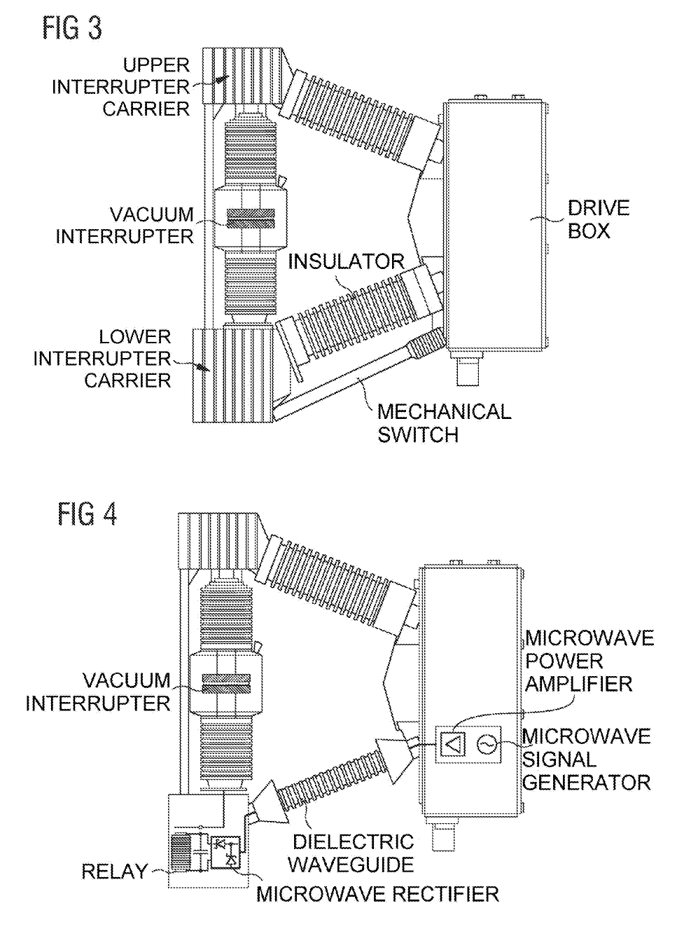

In order to illustrate one or more of the present embodiments, one of these elements of the circuit breaker is shown in a side illustration in FIG. 3. The vacuum interrupter VACUUM INTERRUPTER in the circuit breaker arrangement is fixed between an upper interrupter carrier and a lower interrupter carrier. Each of the upper interrupter carrier and the lower interrupter carrier is connected, according to the prior art, to a drive box DRIVE BOX via an insulator INSULATOR. The drive box DRIVE BOX moves the movable bolt during the switching operation via a mechanical switch MECHANICAL SWITCH, as stated above.

During each switching operation described above, a spring (not illustrated) is mechanically tensioned or relaxed. The switching operations are therefore subject to a high mechanical load and, under certain circumstances, wear out in the case of frequent switching operations, which reduces the maximum number of switching cycles.

Proceeding from the arrangement shown in FIG. 3, FIG. 4 therefore shows how an exemplary embodiment improves the circuit breaker. Reference is therefore made to the elements that remain unchanged in FIG. 3 and to elements with omission/modification that is described using the reference symbols from FIG. 3.

The improvement is based in this case on the use of radio-frequency energy as actuator energy for actuating the switch of the vacuum interrupter VACUUM INTERRUPTER and to transmit this to the switch for this purpose. The transmission may be carried out, for example, by a dielectric waveguide DIELECTRIC WAVEGUIDE. Alternatively, the radio-frequency energy may also be transmitted in radiated fashion or using another waveguide that is not dielectric.

The mechanical actuator MECHANICAL SWITCH may be in the form of an electromagnet.

In the exemplary embodiment illustrated, the vacuum interrupter is switched electrically (e.g., with the aid of a relay RELAY).

Instead of the lower insulator INSULATOR, a dielectric waveguide DIELECTRIC WAVEGUIDE is fitted in the exemplary embodiment shown. The dielectric waveguide has the advantage that the dielectric waveguide simultaneously insulates, stabilizes, and enables the transmission of the power used for the switching operation. Any possible heat produced may be dissipated via this waveguide DIELECTRIC WAVEGUIDE.

A signal generator MICROWAVE SIGNAL GENERATOR that uses a power amplifier MICROWAVE POWER AMPLIFIER to generate the required RF power signal (e.g., in the microwave or mm-wave range) that is then rectified at the other end of the dielectric waveguide DIELECTRIC WAVEGUIDE (e.g., on the side of the vacuum interrupter VACUUM INTERRUPTER) by a rectifier device MICROWAVE RECTIFIER and is supplied to the relay RELAY.

In this case, a plurality of rectifiers may be operated in a parallel manner as alternative developments for higher RF powers. The rectifier may include one or more diodes. The diodes may be Schottky diodes or other diodes, or may be modified transistors. The semiconductors may be based on a GaAs or GaN technology or another technology.

The rectifier may also be developed by being buffered or stabilized by corresponding circuitry measures. For example, the DC power may be buffered in a capacitance and may then be made available to the actuator (e.g., the relay RELAY) for actuating the vacuum switch VACUUM INTERRUPTER.

The waveguide may consist of aluminum oxide, Teflon, HDPE or another solid dielectric material. Hot-pressed silicon carbide (SiC, εᵣ=40, thermal conductivity 90-160 W cm⁻¹ K⁻¹⇄Cu 240-380 W cm⁻¹ K⁻¹) may also be considered for high thermal conductivity for the purpose of dissipating heat.

In addition, in one embodiment, the waveguide may consist of a tube filled with a corresponding dielectric liquid. In this case, the waveguide may be straight or may also assume complex forms that are produced using any desired known production method.

The entire assembly may be cast, which may be an advantage over switching linkages. Further advantages of this may be the avoidance of sparkovers, climatic encapsulation, or improved cooling.

One or more tubes may be operated in a parallel manner inside the assembly, which may result in economic advantages, for example. Parallel or serial operation is facilitated by the possibility of achieving a high degree of switching synchronicity using simple electromechanical measures. This switching synchronicity may be achieved by being able to superimpose a suitable trigger signal on the radio-frequency signal transmitting the energy.

The mechanical actuator MECHANICAL SWITCH or other parts on the interrupter or the entire arrangement may be equipped with sensors that measure relevant operating information. The information may be simultaneously transmitted back via the waveguide DIELECTRIC WAVEGUIDE during the power transmission.

Other forms of energy conversion without rectifiers for actuating the switch may also be provided. For example, operation during which the RF energy is used to heat a gas volume may be provided. This gas volume expands on account of the heating and therefore drives a piston connected to the tube. This enables a slow switching operation. Instead of the gas, the use of water that is heated by the RF energy, is evaporated, and therefore drives a piston may also be provided.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1.-10. (canceled)

11. An arrangement for switching open contact gaps using switching devices, the arrangement being configured such that direct current (DC)-isolated energy transmission of radio-frequency energy provides actuator energy for at least one of the switching devices, the arrangement comprising:
the at least one switching device, which comprises a vacuum interrupter, a switching device of the at least one switching device being mechanically connected to a radio-frequency source in a non-conductive manner via a dielectric waveguide arranged in a direction of an open contact gap of the vacuum interrupter for energy transmission,
wherein the switching device comprises a converter configured to convert the transmitted radio-frequency energy into actuator energy, the converter comprising at least one rectifier arrangement and electrically operated switches connected downstream of the radio-frequency energy transmission as actuators.

12. The arrangement of claim 11, wherein the electrically operated switches comprise relay switches,

13. The arrangement of claim 11, wherein the arrangement is configured such that, for the purpose of transmitting energy, the radio-frequency energy is emitted as electromagnetic waves to the switching device, the switching device being configured to convert the transmitted radio-frequency energy into actuator energy.

14. The arrangement of claim 11, wherein the at least one rectifier arrangement comprises at least two parallel rectifier arrangements.

15. The arrangement of claim 13, wherein the at least one rectifier arrangement comprises at least two parallel rectifier arrangements.

16. The arrangement of claim 11, wherein the dielectric waveguide comprises a solid dielectric material.

17. The arrangement of claim 16, wherein the solid dielectric material is aluminum oxide, Teflon, HDPE or hot-pressed silicon carbide.

18. The arrangement of claim 13, wherein the dielectric waveguide comprises a solid dielectric material.

19. The arrangement of claim 18, wherein the solid dielectric material is aluminum oxide, Teflon, HDPE or hot-pressed silicon carbide.

20. The arrangement of claim 14, wherein the dielectric waveguide comprises a solid dielectric material.

21. The arrangement of claim 20, wherein the solid dielectric material is aluminum oxide, Teflon, HDPE or hot-pressed silicon carbide.

22. The arrangement of claim 11, wherein the dielectric waveguide is formed from a flexible material filled with dielectric liquids.

23. The arrangement of claim 13, wherein the dielectric waveguide is formed from a flexible material filled with dielectric liquids.

24. The arrangement of claim 16, wherein the dielectric waveguide is formed from a flexible material filled with dielectric liquids.

25. The arrangement of claim 11, further comprising sensors, at least parts of elements of the arrangement comprising the sensors.
